(19) United States
(12) Patent Application Publication
(10) Pub. No.: US 2015/0004340 A1
(43) Pub. Date: Jan. 1, 2015

(54) HOUSING OF ELECTRONIC DEVICE AND METHOD FOR MANUFACTURING THE HOUSING

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventors: Hong-Ye ZHANG, Shenzhen (CN); Chung-Chi TSENG, New Taipei (TW)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 14/016,241

(22) Filed: Sep. 3, 2013

(30) Foreign Application Priority Data
Jun. 28, 2013 (CN) 2013102637109

(51) Int. Cl. B32B 37/00; H05K 5/02

(52) U.S. Cl. CPC B32B 37/0038; H05K 5/02
USPC 428/36.1; 264/255

(57) ABSTRACT

A method to manufacture a housing of an electronic device includes providing a fiber cloth impregnated with resin. Providing a film attached to one side surface of the fiber cloth. Placing the fiber cloth together with the film in a hot-press die to adhere the film to the fiber cloth to form a fiber cloth layer and a film layer. Placing the fiber cloth layer and the film layer in a female mold. Providing a male mold closed to the female mold, then injecting molten resin into the female mold to form a resin layer, with the resin layer and the film layer integrated to a unitary body when injecting. Then cooling the female mold and the male mold, and then opening the male mold to retrieve the housing.

### BACKGROUND

1. Technical Field

The disclosure relates to a housing of an electronic device.

2. Description of Related Art

Plastic articles are reinforced by adding fiber to the housing. The traditional method for manufacturing the housing is to attach the fiber layers to the plastic article through adhering, which uses glue. Therefore, it is complex to manufacture the housing.

### BRIEF DESCRIPTION OF THE DRAWINGS

FIG. 1 is a flowchart of a first embodiment of a method for manufacturing a housing.

FIG. 2 is a schematic view showing a hot-pressing process of the method of the first embodiment of FIG. 1.

FIG. 3 is a schematic view showing an injecting molding of the method of the first embodiment of FIG. 1.

FIG. 4 is a cross-sectional view of the housing manufactured by the first method of FIG. 1.

FIG. 5 is a flowchart of a second embodiment of a method for manufacturing a housing.

FIG. 6 is a schematic view showing a hot-pressing process of the method of the second embodiment of FIG. 5.

FIG. 7 is a schematic view showing an injecting molding of the method of the second embodiment of FIG. 5.

FIG. 8 is a cross-sectional view of the housing manufactured by the second method of FIG. 5.

### DETAILED DESCRIPTION

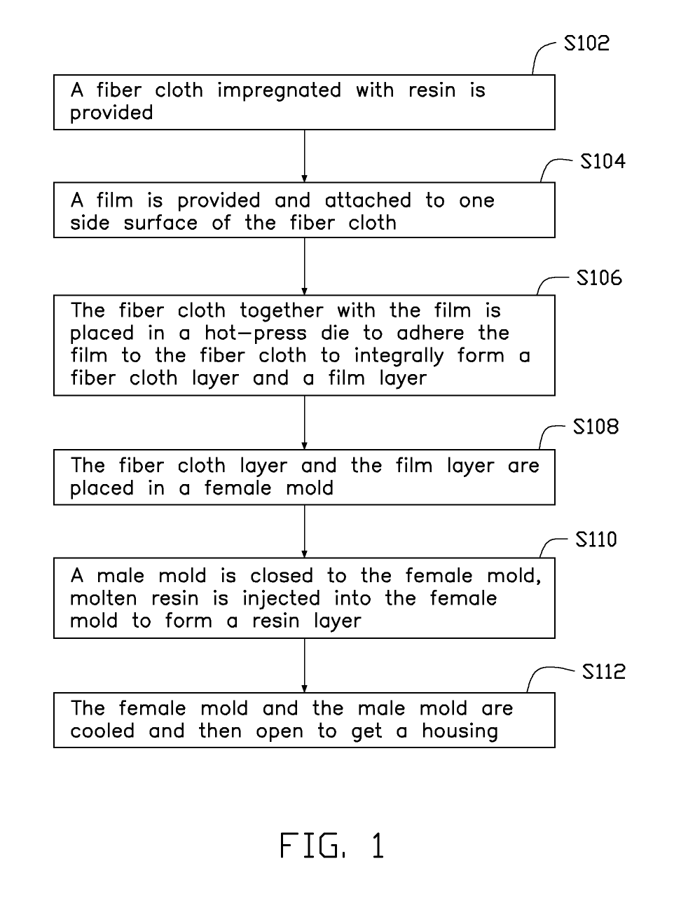

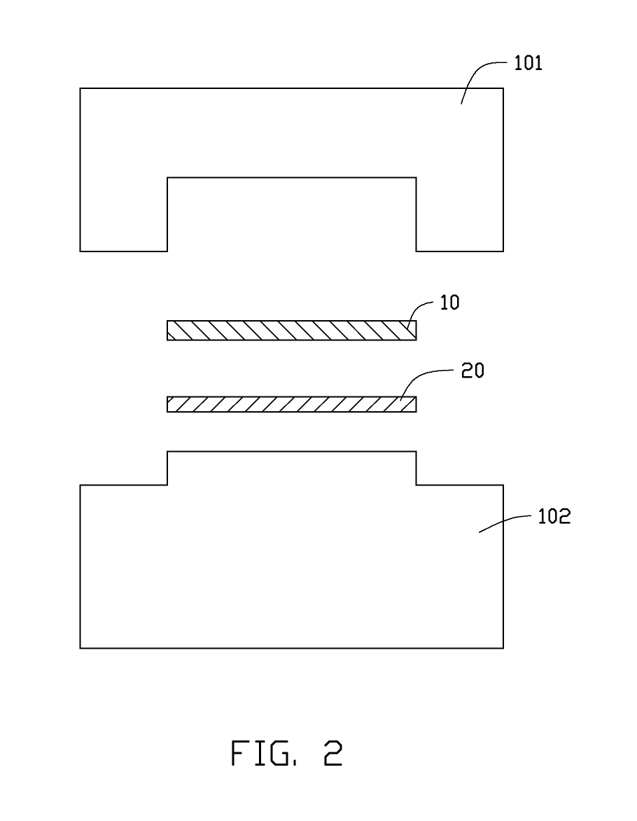

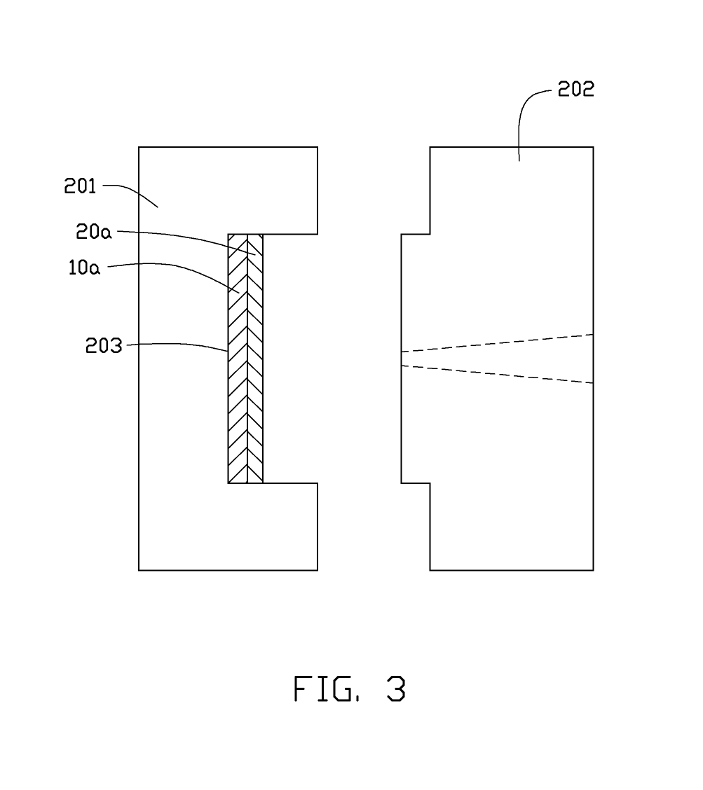

FIG. 1 to FIG. 4 show a first embodiment of a method to manufacture a housing of an electronic device. The method includes the following steps.

In step S102, a fiber cloth 10 impregnated with resin is provided, wherein the fiber cloth 10 is selected from the group consisting of carbon fiber cloth impregnated with thermoplastic resin, glass fiber cloth impregnated with thermoplastic resin, and unidirectional ruled cloth impregnated with thermoplastic resin.

In step S104, a film 20 is provided and attached to one side surface of the fiber cloth 10. The thickness of the film 20 can range from about 0.05 millimeters to about 1.0 millimeter. The film 20 may be made from at least one of a plurality of resin materials including polycarbonate, acrylonitrile-butadiene-styrene, polyamine formate, polymethyl methacrylate, and polyethylene terephthalate.

In step S106, the fiber cloth 10 together with the film 20 is placed in a hot-press die 101 and 102 to adhere the film 20 to the fiber cloth 10 to form a fiber cloth layer 10a and a film layer 20a.

In step S108, the fiber cloth layer 10a and the film layer 20a are placed in a cavity of a female mold 201, with the fiber cloth layer 10a contacting with an inner surface 203 of the cavity of the female mold 201.

In step S110, a male mold 202 is closed to the female mold 201, molten resin is injected into the cavity of the female mold 201 to form a resin layer 30. The molten resin is selected from the group consisting of polycarbonate, acrylonitrile-butadiene-styrene, polyamine formate, polymethyl methacrylate, and polyethylene terephthalate. In this embodiment, the material of the molten resin is same as the film 20. The resin layer 30 and the film layer 20a are integrated to a unitary body.

In step S112, the female mold 201 and the male mold 202 are cooled and then opened to retrieve a housing 40.

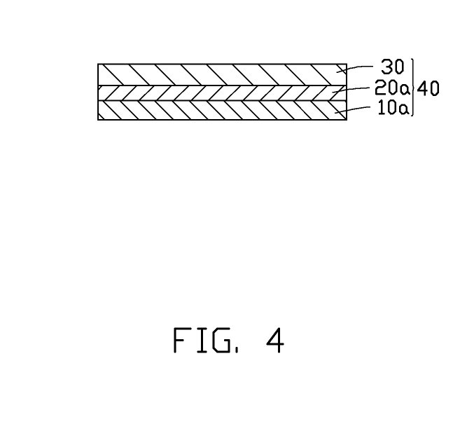

FIG. 4 shows that the housing 40 includes a fiber cloth layer 10a, a film layer 20a attached to one side surface of the fiber cloth layer 10a, and a resin layer 30 formed by injecting molten resin to the film layer 20a. The film layer 20a is located between the fiber cloth layer 10a and the resin layer 30.

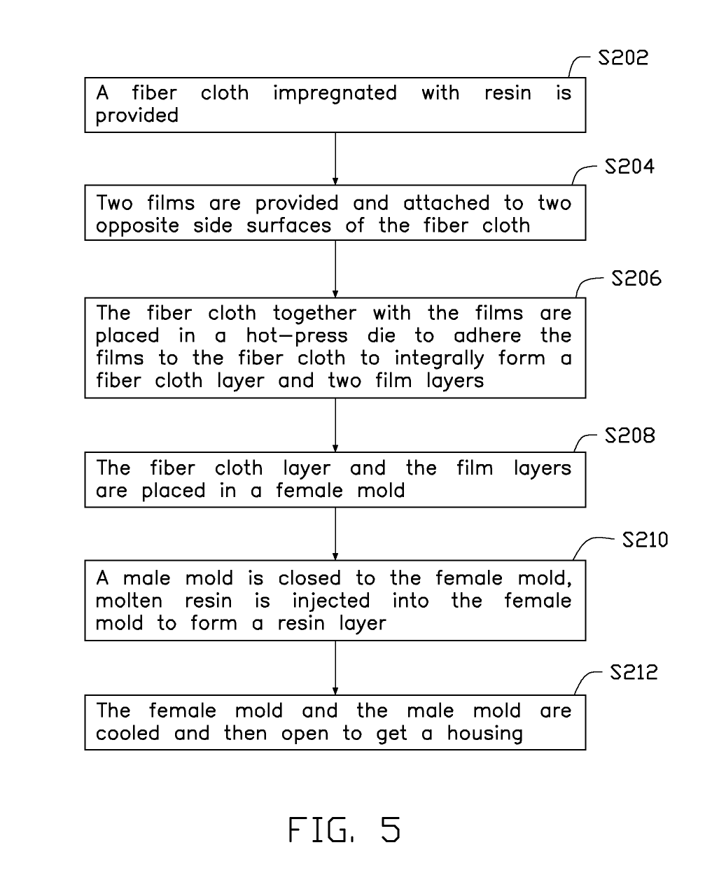

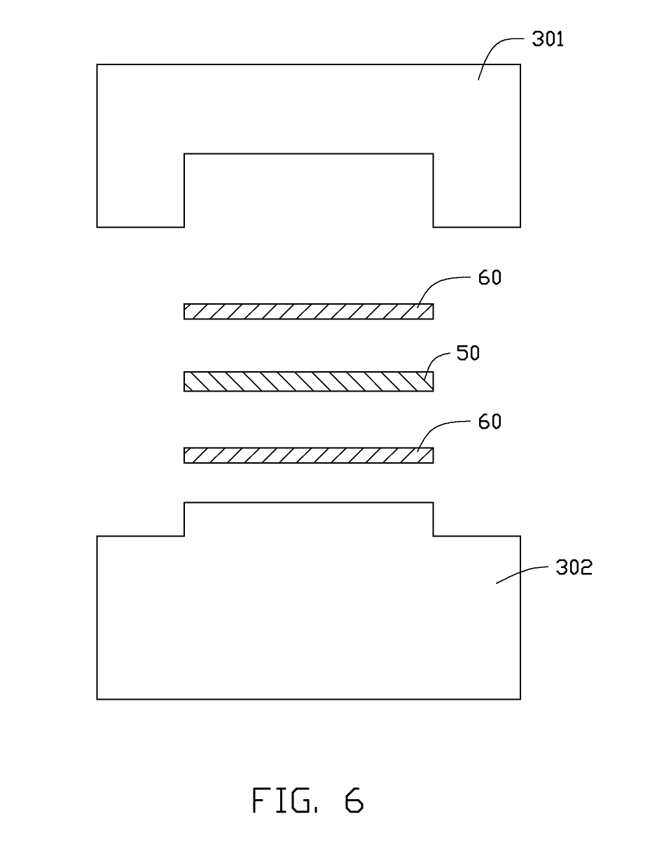

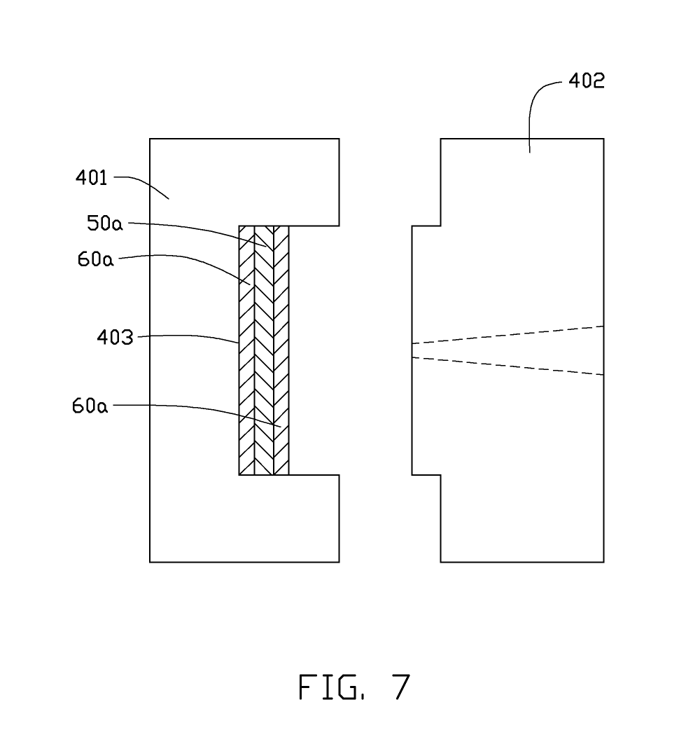

FIG. 5 to FIG. 8 show a second embodiment of a method to manufacture a housing of an electronic device. The method includes the following steps.

In step S202, a fiber cloth 50 impregnated with resin is provided, wherein the fiber cloth 50 is selected from the group consisting of carbon fiber cloth impregnated with thermoplastic resin, glass fiber cloth impregnated with thermoplastic resin, and unidirectional ruled cloth impregnated with thermoplastic resin.

In step S204, two films 60 are provided and attached to two opposite side surfaces of the fiber cloth 50. The thickness of the film 60 can range from about 0.05 millimeters to about 1.0 millimeter. The film 60 may be made from at least one of a plurality of resin materials including polycarbonate, acrylonitrile-butadiene-styrene, polyamine formate, polymethyl methacrylate, and polyethylene terephthalate.

In step S206, the fiber cloth 50 together with the films 60 are placed in a hot-press die 301 and 302 to adhere the films 60 to the fiber cloth 50 to form a fiber cloth layer 50a and two film layers 60a.

In step S208, the fiber cloth layer 50a and the film layers 60a are placed in a cavity of a female mold 401, with one of the film layers 60a contacting with an inner surface 403 of the cavity of the female mold 401.

In step S210, a male mold 402 is closed to the female mold 401, molten resin is injected into the cavity of the female mold 401 to form a resin layer 70. The molten resin is selected from the group consisting of polycarbonate, acrylonitrile-butadiene-styrene, polyamine formate, polymethyl methacrylate, and polyethylene terephthalate. In this embodiment, the material of the molten resin is the same as the film 60. The resin layer 70 and one of the film layers 60a facing the resin layer 70 are integrated to a unitary body. The other one of the film layers 60a is coated on the fiber cloth layer 50a, for protecting the fiber cloth layer 50a from being damaged.

In step S212, the female mold 401 and the male mold 402 are cooled and then opened to retrieve a housing 80.

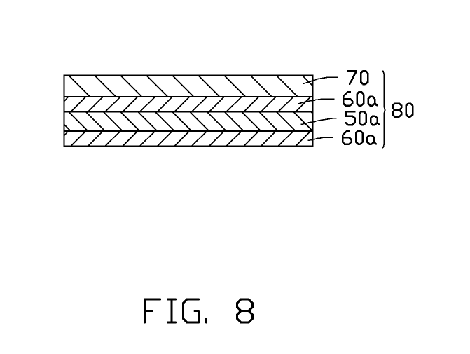

FIG. 8 shows that the housing 80 includes a fiber cloth layer 50a, two film layers 60a attached opposite side surfaces of the fiber cloth layer 50a, and a resin layer 70 by injecting molten resin to one of the film layers 60a. The other one of the film layers 60a is coated on the fiber cloth layer 50a, for protecting the fiber cloth layer 50a from being damaged.

In the present disclosure, the material of the molten resin is same as or similar to the material of the film 20 or the films 60, thus the resin layer 30 and 70 and the film layer 20a and 60a are integrated to a unitary body when injecting, which can save time.

It is believed that the present embodiments and their advantages will be understood from the foregoing description, and it will be apparent that various changes may be made thereto without departing from the spirit and scope of the description or sacrificing all of its material advantages, the examples hereinbefore described merely being exemplary embodiments.

What is claimed is:

1. A method for forming a housing of an electronic device, comprising:
providing a fiber cloth impregnated with resin;
providing a film attached to one side surface of the fiber cloth;
placing the fiber cloth together with the film in a hot-press die to adhere the film to the fiber cloth, thereby forming a fiber cloth layer and a film layer;
placing the fiber cloth layer and the film layer in a female mold;
providing a male mold closed to the female mold, then injecting molten resin into the female mold to form a resin layer, with the resin layer and the film layer integrated to a unitary body when injecting; and
cooling the female mold and the male mold, and then opening the male mold to retrieve the housing.

2. The method of claim 1, wherein the fiber cloth is selected from the group consisting of carbon fiber cloth impregnated with thermoplastic resin, glass fiber cloth impregnated with thermoplastic resin, and unidirectional ruled cloth impregnated with thermoplastic resin.

3. The method of claim 1, wherein a thickness of the film ranges from about 0.05 millimeters to about 1.0 millimeter.

4. The method of claim 1, wherein the film is made from at least one of a plurality of resin materials including polycarbonate, acrylonitrile-butadiene-styrene, polyamine formate, polymethyl methacrylate, and polyethylene terephthalate.

5. The method of claim 1, wherein the material of the molten resin is same as or similar to the material of the film.

6. A method for forming a housing of an electronic device, comprising:
providing a fiber cloth impregnated with resin;
providing two films attached to opposite side surfaces of the fiber cloth;
placing the fiber cloth together with the films in a hot-press die to adhere the films to the fiber cloth to form a fiber cloth layer and two film layers;
placing the fiber cloth layer and the film layers in a female mold;
providing a male mold closed to the female mold, then injecting molten resin into the female mold to form a resin layer, with the resin layer and one of the film layers integrated to a unitary body when injecting; and
cooling the female mold and the male mold, and then opening the male mold to retrieve the housing.

7. The method of claim 6, wherein the fiber cloth is selected from the group consisting of carbon fiber cloth impregnated with thermoplastic resin, glass fiber cloth impregnated with thermoplastic resin, and unidirectional ruled cloth impregnated with thermoplastic resin.

8. The method of claim 6, wherein a thickness of the films ranges from about 0.05 millimeters to about 1.0 millimeter.

9. The method of claim 6, wherein the films are made from at least one of a plurality of resin materials including polycarbonate, acrylonitrile-butadiene-styrene, polyamine formate, polymethyl methacrylate, and polyethylene terephthalate.

10. The method of claim 6, wherein the material of the molten resin is same as or similar to the material of the films.

11. A housing of an electronic device, comprising:
a fiber cloth layer;
a first film layer attached to one surface of the fiber cloth layer; and
a resin layer attached to the film layer by injecting molten resin to the film layer;
wherein the first film layer is located between the fiber cloth layer and the resin layer.

12. The housing of claim 11, wherein a second film layer is coated on the fiber cloth layer opposite to the first film layer.
